(19) United States
(12) Patent Application Publication
(10) Pub. No.: US 2008/0129852 A1
(43) Pub. Date: Jun. 5, 2008

(54) Image sensor, method of manufacturing the same, and camera module having the same

(75) Inventor: Kyoung Tai Lee, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/987,780

(22) Filed: Dec. 4, 2007

(30) Foreign Application Priority Data
Dec. 5, 2006 (KR) 10-2006-0122503

(51) Int. Cl. H04N 5/335; H01L 21/00

(52) U.S. Cl. 348/294; 438/69; 257/E21.001; 348/E05.091

(57) ABSTRACT

Provided is an image sensor including a wafer; a plurality of light receiving elements provided on the wafer; a color filter provided above the light receiving elements so as to overlap the light receiving elements; an infrared (IR) filter layer provided on the color filter, the IR filter layer having a plane surface parallel to an array direction of the light receiving elements; and a plurality of micro lenses provided on the IR filter layer.

### CROSS-REFERENCE TO RELATED APPLICATIONS

This application claims the benefit of Korean Patent Application No. 10-2006-0122503 filed with the Korea Intellectual Property Office on Dec. 5, 2006, the disclosure of which is incorporated herein by reference.

### BACKGROUND OF THE INVENTION

1. Field of the Invention

The present invention relates to an image sensor, a method of manufacturing the same, and a camera module having the same.

2. Description of the Related Art

With the recent development of mobile terminals such as portable phones and personal digital assistants (PDAs), the mobile terminals provide a phone call function and are used as multi-convergence devices. The most representative of the multi-convergence is a camera module. The resolution of the camera module changes from 300,000 pixels (VGA) to 8,000,000 pixels. Moreover, the camera module provides various additional functions, such as auto-focusing (AF) and optical zoom. Generally, camera modules are applied to various IT devices, such as camera phones, smart phones, and mobile communication terminals.

The camera modules are manufactured by using main parts of charge coupled device (CCD) or complementary metal oxide semiconductor (CMOS) image sensors. Incident light transmitted through the lens is condensed by the image sensor and is stored as data in the memory. The stored data is displayed as an image through a display medium, such as liquid crystal display (LCD) or PC monitor.

Packaging methods of the image sensor for camera module include a chip on film (COF) method, a chip on board (COB) method and so on. Referring to accompanying drawings, a camera module manufactured by the COB method will be described.

FIG. 1 is an exploded view of a conventional COB camera module. FIG. 2 is a cross-sectional view schematically showing the structure of a conventional image sensor. FIG. 3 is a cross-sectional view schematically showing the structure of a conventional infrared (IR) filter.

As shown in FIG. 1, the conventional camera module includes a substrate 1 having an image sensor 2 mounted thereon, the image sensor 2 converting light incident through a lens into an electrical signal; a housing 4 installed on the substrate 1; a lens group L for concentrating image signals of an object into the image sensor 2; and a lens barrel 5 in which the lens group L is stacked in multilayer.

The housing 4 has a step portion (not shown) formed in a lower inner side thereof, and an IR shielding member 3 is installed in the step portion. Further, the IR shielding member 3 serves to cut off infrared light from light incident on the image sensor 2 through the lens group L.

Meanwhile, after the housing 4 to which the substrate 1 having the image sensor 2 mounted thereon and the lens barrel 5 are coupled is bonded and fixed, focus adjustment is carried out in a state where an object (resolution chart) is set in front of the lens barrel 5 at a predetermined distance. The focus adjustment of the camera module is performed as follows. As the lens barrel 5 coupled to the housing 4 through a screw is rotated, the vertical movement amount of the lens barrel 5 is adjusted. Then, the focus adjustment between the lens group L and the image sensor 2 is performed.

At this time, the focus adjustment is performed in a state where the distance from the object is set in the range of 50 cm to the infinity. After the focus adjustment is completed, an adhesive is injected between the housing 4 and the lens barrel 5 such that the housing 4 and the lens barrel 5 are bonded and fixed to each other.

As shown in FIG. 2, the image sensor 2 includes a silicon wafer 2a, a plurality of light receiving elements 2b such as photodiodes formed on the silicon wafer 2a, a metal layer 2c formed on the light receiving elements 2b and composing a circuit unit, a color filter 2d formed on a pixel array region of the metal layer 2c so as to overlap the light receiving elements 2b, and a plurality of micro lenses 2e formed on the color filter 2d.

The micro lenses 2e are formed in a hemispheric shape and serve to concentrate light incident through the lens group L into the light receiving elements 2b.

The metal layer 2c serves to connect a power line or signal line to the light receiving elements 2b, a logic circuit and so on. Further, the metal layer 2c serves as a shield for preventing light from being incident on a region excluding the light receiving elements 2b.

To cut off infrared light from light incident on the image sensor 2, the IR shielding member 3 is provided in the step portion of the housing 4. As shown in FIG. 3, the IR shielding member 3 is manufactured by forming an IR shielding material 3b on a glass substrate 3a serving as a base.

The IR shielding material 3b is formed by a vacuum thin-film deposition technique. That is, two kinds of materials having a different refractive index, for example, TiO₂ and SiO₂ or Ta₂O₅ and SiO₂ are alternately deposited on the glass substrate 3a.

However, the conventional camera module constructed in such a manner has the following problems.

That is, a separate process of mounting the IR shielding member 3 on the housing 4 should be performed. Further, while the housing 4 is coupled to the substrate 1 having the image sensor 2 mounted thereon after the IR shielding member 3 is mounted on the housing 4, various foreign matters are generated in the IR shielding member 3 or the image sensor 2.

Further, to mount the IR shielding member 3, the glass substrate 3a having the IR shielding material 3b formed thereon should be cut so as to be fitted into the step portion of the housing 4. Therefore, during the cutting process, foreign matters may be generated, and a cut portion of the glass substrate 3a may be damaged once again. Further, while the cut IR shielding member 3 is bonded to the housing 4 through an adhesive, foreign matters may be generated in the IR shielding member 3.

In the conventional camera module, the IR shielding member 3 is provided on the image sensor 2. Therefore, an effect of cutting off infrared light incident on the image sensor 2 decreases.

As shown in FIG. 3, when light passing through the lens group L is incident on the IR shielding member 3, infrared light included in light which is vertically incident is cut off, but infrared light included in light which is obliquely incident passes through the IR shielding member 3 so as to enter the image sensor 2. Therefore, a color shift phenomenon occurs in the image sensor 2.

More specifically, the IR shielding member 3 cuts off infrared light included in light incident within the range of 15 degrees to both sides on the basis of vertical light, but cannot cut off infrared light included in light incident at an angle more than 15 degrees.

### SUMMARY OF THE INVENTION

An advantage of the present invention is that it provides an image sensor, a method of manufacturing the same, and a camera module having the same, in which incidence of infrared light on the image sensor is minimized, foreign matters are prevented from being generated, and a manufacturing process of the camera module is simplified so as to reduce a process time and manufacturing cost.

Additional aspects and advantages of the present general inventive concept will be set forth in part in the description which follows and, in part, will be obvious from the description, or may be learned by practice of the general inventive concept.

According to an aspect of the invention, an image sensor comprises a wafer; a plurality of light receiving elements provided on the wafer; a color filter provided above the light receiving elements so as to overlap the light receiving elements; an infrared (IR) filter layer provided on the color filter, the IR filter layer having a plane surface parallel to an array direction of the light receiving elements; and a plurality of micro lenses provided on the IR filter layer.

Preferably, the IR filter is formed by a vacuum thin-film deposition technique.

Preferably, each of the micro lenses has such an upper curvature that light incident on the IR filter layer through the micro lens is incident at less than 15 degrees with respect to vertical light.

According to another aspect of the invention, an image sensor comprises a wafer; a plurality of light receiving elements provided on the wafer; an IR filter layer provided above the light receiving elements, the IR filter layer having a plane surface parallel to an array direction of the light receiving elements; a color filter provided on the IR filter layer so as to overlap the light receiving elements; and a plurality of micro lenses provided on the color filter.

Preferably, each of the micro lenses has such an upper curvature that light incident on the IR filter layer through the micro lens is incident at less than 15 degrees with respect to vertical light.

Preferably, each of the micro lenses has such an upper curvature that light incident on the IR filter layer through the micro lens is incident at less than 15 degrees with respect to vertical light.

According to a further aspect of the invention, a method of manufacturing an image sensor comprises the steps of: forming a plurality of light receiving elements on a wafer; forming a color filter above the light receiving elements such that the color filter overlaps the light receiving elements; forming an IR filter layer on the color filter, the IR filter layer having a plane surface parallel to an array direction of the light receiving elements; and forming a plurality of micro lenses on the IR filter layer.

Preferably, the IR filter is formed by a vacuum thin-film deposition technique.

Preferably, each of the micro lenses has such an upper curvature that light incident on the IR filter layer through the micro lens is incident at less than 15 degrees with respect to vertical light.

According to a still further aspect of the invention, a method of manufacturing an image sensor comprises the steps of: forming a plurality of light receiving elements on a wafer; forming an IR filter layer above the light receiving elements, the IR filter layer having a plane surface parallel to an array direction of the light receiving elements; forming a color filter on the IR filter layer such that the color filter overlaps the light receiving elements; and forming a plurality of micro lenses on the color filter.

Preferably, the IR filter is formed by a vacuum thin-film deposition technique.

Preferably, each of the micro lenses has such an upper curvature that light incident on the IR filter layer through the micro lens is incident at less than 15 degrees with respect to vertical light.

According to a still further aspect of the invention, a camera module comprises an image sensor, a substrate having the image sensor mounted thereon; a housing installed on the substrate; and a lens barrel installed on the housing and having a lens group mounted thereon. The image sensor includes a wafer; a plurality of light receiving elements provided on the wafer; a color filter provided above the light receiving elements so as to overlap the light receiving elements; an IR filter layer provided on the color filter, the IR filter layer having a plane surface parallel to an array direction of the light receiving elements; and a plurality of micro lenses provided on the IR filter layer.

According to a still further aspect of the invention, a camera module comprises an image sensor, a substrate having the image sensor mounted thereon; a housing installed on the substrate; and a lens barrel installed on the housing and having a lens group mounted thereon. The image sensor includes a wafer; a plurality of light receiving elements provided on the wafer; an IR filter layer provided above the light receiving elements, the IR filter layer having a plane surface parallel to an array direction of the light receiving elements; a color filter provided on the IR filter layer so as to overlap the light receiving elements; and a plurality of micro lenses provided on the color filter.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an exploded view of a conventional COB camera module;

FIG. 2 is a cross-sectional view schematically showing the structure of a conventional image sensor;

FIG. 3 is a cross-sectional view schematically showing the structure of a conventional IR filter;

FIG. 4 is a cross-sectional view schematically showing the structure of an image sensor according to a first embodiment of the present invention;

FIG. 5 is an expanded view of a portion A of FIG. 4;

FIG. 6 is a diagram for explaining a method of manufacturing the image sensor according to the first embodiment of the invention;

FIG. 7 is a cross-sectional view schematically showing the structure of an image sensor according to a second embodiment of the invention;

FIG. 8 is an expanded view of a portion B of FIG. 7;

FIG. 9 is a diagram for explaining a method of manufacturing the image sensor according to the second embodiment of the invention; and

FIG. 10 is an exploded perspective view of a COB camera module to which the image sensor according to the invention is applied.

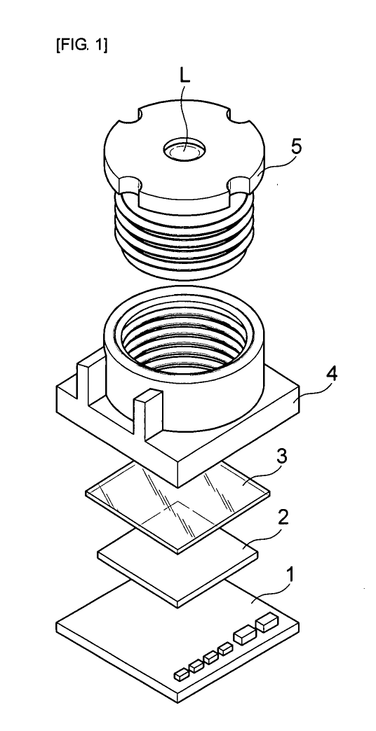

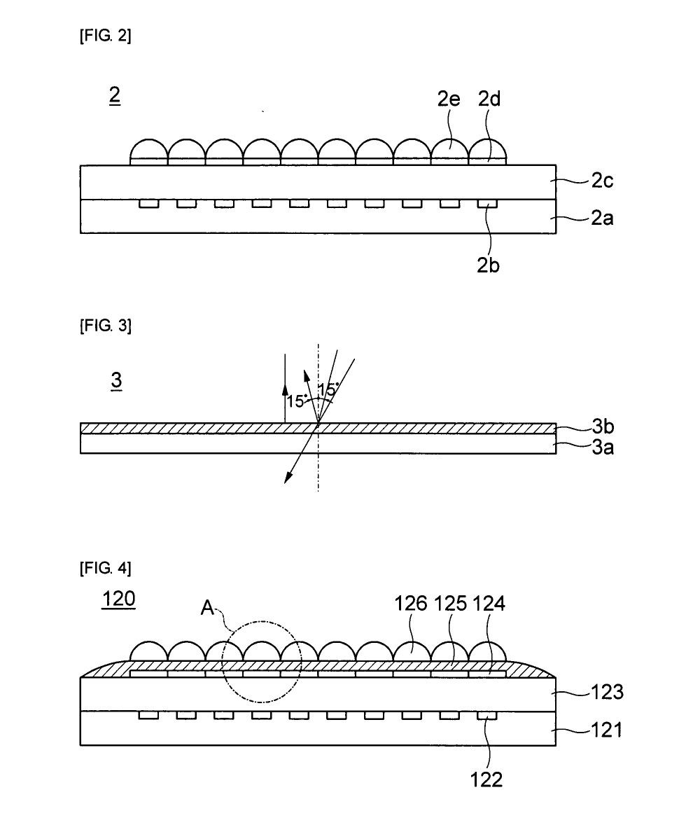

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, embodiments of the present invention will be described in detail with reference to the accompanying drawings.

### First Embodiment of Image Sensor

Referring to FIGS. 4 to 6, an image sensor according to a first embodiment of the invention will be described.

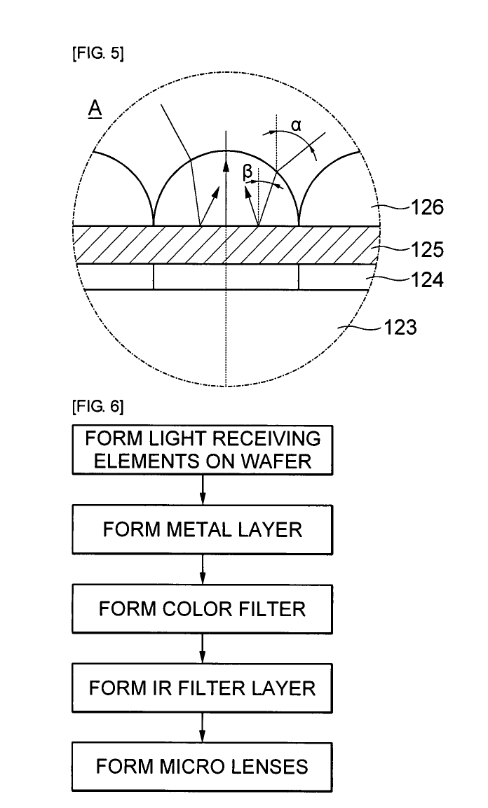

FIG. 4 is a cross-sectional view schematically showing the structure of an image sensor according to a first embodiment of the invention. FIG. 5 is an expanded view of a portion A of FIG. 4. FIG. 6 is a diagram for explaining a method of manufacturing the image sensor according to the first embodiment of the invention.

As shown in FIG. 4, the image sensor 120 according to the first embodiment of the invention includes a wafer 121, a plurality of light receiving elements 122 formed on the wafer 121, a metal layer 123 formed on the light receiving elements 122 and composing a circuit unit, a color filter 124 formed on a pixel array region of the metal layer 123 so as to overlap the light receiving elements 122, an IR filter layer 125 formed on the color filter 124 so as to have a plane surface parallel to an array direction of the light receiving elements 122, and a plurality of micro lenses 126 formed on the IR filter layer 125.

The metal layer 123 serves to connect a power supply line or signal line to the light receiving elements, a logic circuit and so on. The metal layer 123 serves as a shield for preventing light from being incident on a region excluding the light receiving elements 122.

The IR filter layer 125 is formed by a vacuum thin-film deposition technique. In the vacuum thin-film deposition technique, a metal or compound is heated and evaporated in a vacuum state such that the vapor thereof is deposited on the surface of an object in the form of thin film. The vacuum thin-film deposition technique is mainly used when a lens coating or a coating layer of an electronic part or semiconductor is formed.

That is, the IR filter layer 125 is formed by depositing a material, which cuts off infrared light, on the color filter 124 through the vacuum thin-film deposition technique.

At this time, the IR filter layer 125 is formed with a uniform thickness. Further, the IR filter layer 125 is formed to have a plane top surface parallel to the array direction of the light receiving elements 122 such that the refractive index thereof becomes uniform. Therefore, it is possible to maximize an IR shielding effect and to prevent irregular reflection.

As for the vacuum thin-film deposition technique, a coating method may be used. Alternately, a sputtering method may be used, which ionizes an IR shielding material to sputter onto a color filter.

Further, the micro lenses 126 with a hemispheric shape are formed on the IR filter layer 125 so as to concentrate light into the light receiving elements.

As shown in FIG. 5, it is preferable that each of the micro lenses 126 has such an upper curvature that light incident on the IR filter layer 125 through the micro lens 126 is incident at about 15 degrees with respect to vertical light.

The IR shielding material serves to cut off infrared light incident at less than 15 degrees with respect to vertical light. Therefore, although light incident on the upper surface of the micro lens 126 has an angle α more than 15 degrees with respect to vertical light, the light passing through the upper surface of the micro lens 126 is concentrated into the center of the light receiving element 122 at an angle β less than 15 degrees, because the upper curvature of the micro lens 126 is limited as described above. Accordingly, the light incident on the top surface of the IR filter layer 125 is also incident at an angle less than 15 degrees with respect to vertical light such that infrared light included in most light is reflected, which makes it possible to maximize an IR shielding effect.

Therefore, an amount of infrared light incident on the image sensor 120 is minimized, so that a color shift phenomenon of the image sensor 120 can be effectively prevented.

Now, a method of manufacturing the image sensor according to the first embodiment of the invention will be described.

As shown in FIG. 6, the method includes the steps of: forming a plurality of light receiving elements 122 on a wafer 121; forming a metal layer 123 on the light receiving elements 122; forming a color filter 124 on the metal layer 123 such that the color filter 124 overlaps the light receiving elements 122; forming an IR filter layer 125 on the color filter 124, the IR filter layer having a plane surface parallel to an array direction of the light receiving elements 122; and forming a plurality of micro lenses 126 on the IR filter layer 125.

The IR filter layer 125 is formed by the vacuum thin-film deposition technique such that the thickness thereof is uniform. Further, the top surface of the IR filter layer 125 is formed to be parallel to the array direction of the light receiving elements 122 such that the refractive index thereof is uniform. Then, an IR shielding effect is maximized, and irregular reflection is prevented.

Further, the micro lenses 126 are formed in a hemispheric shape. Preferably, the upper curvature of each micro lens 126 is defined in such a manner that light incident on the IR filter layer 125 is incident at less than 15 degrees with respect to vertical light.

### Second Embodiment of Image Sensor

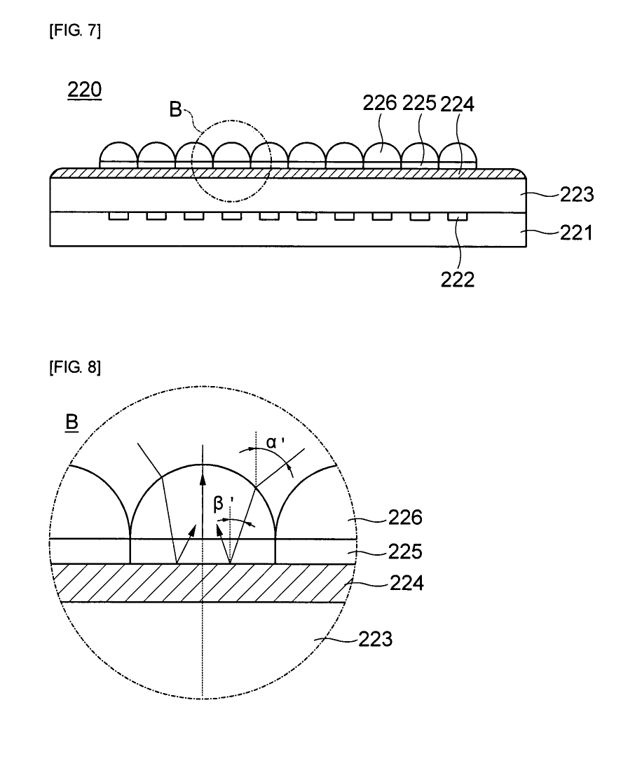

Referring to FIGS. 7 to 9, an image sensor according to a second embodiment of the invention will be described.

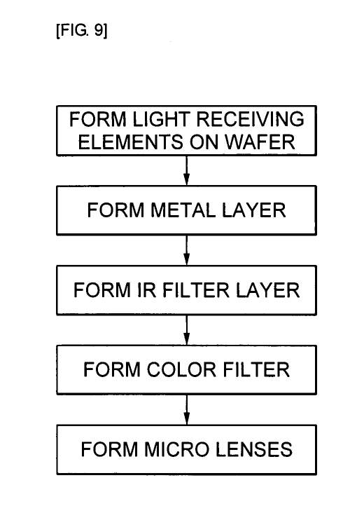

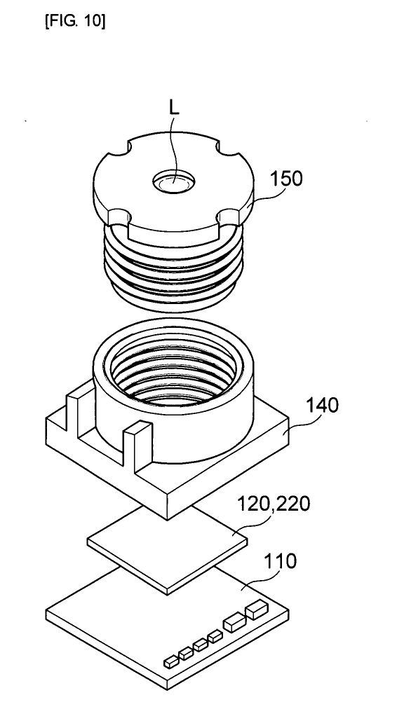

FIG. 7 is a cross-sectional view schematically showing the structure of an image sensor according to a second embodiment of the invention. FIG. 8 is an expanded view of a portion B of FIG. 7. FIG. 9 is a diagram for explaining a method of manufacturing the image sensor according to the second embodiment of the invention.

As shown in FIG. 7, the image sensor 220 according to the second embodiment of the invention includes a wafer 221; a plurality of light receiving elements 222 formed on the wafer 221; a metal layer 223 formed on the light receiving elements 222 and composing a circuit unit; an IR filter layer 224 formed on the metal layer 223, the IR filter layer 224 having a plane surface parallel to an array direction of the light receiving elements 222; a color filter 225 formed on the IR filter 224 so as to overlap the light receiving elements 222; and a plurality of micro lenses 226 formed on the color filter 225.

The metal layer 223 serves to connect a power line or signal line to the light receiving elements 222, a logic circuit and so on. The metal layer 223 serves a shield for preventing light from being incident on a region excluding the light receiving elements 222.

The IR filter layer 224 is formed by the vacuum thin-film deposition technique. In the vacuum thin-film deposition technique, a metal or compound is heated and evaporated in a vacuum state such that the vapor thereof is deposited on the surface of an object in the form of thin film. The vacuum thin-film deposition is mainly used when a lens coating or a coating layer of an electronic part or semiconductor is formed.

That is, the IR filter layer 224 is formed by depositing a material, which cuts off infrared light, on the metal layer 223 through the vacuum thin-film deposition technique.

At this time, the IR filter layer 224 is formed with a uniform thickness. Further, the IR filter layer 224 is formed to have a plane surface parallel to the array direction of the light receiving elements 222 such that the refractive index thereof is uniform. Therefore, it is possible to maximize an IR shielding effect and to prevent irregular reflection.

As for the vacuum thin-film deposition technique, a coating method may be used. Alternately, a sputtering method may be used, which ionizes an IR shielding material to sputter onto the metal layer 223.

Further, the micro lenses 226 with a hemispheric shape are formed on the color filter 225 so as to concentrate light into the light receiving elements 222.

As shown in FIG. 8, it is preferable that each of the micro lenses 226 has such an upper curvature that light incident on the IR filter layer 224 through the micro lens 226 is incident at less than 15 degrees with respect to vertical light.

The IR shielding material serves to cut off infrared light incident at less than 15 degrees with respect to vertical light. Therefore, although light incident on the upper surface of the micro lens 226 has an angle α more than 15 degrees with respect to vertical light, the light passing through the upper surface of the micro lens 226 is concentrated into the center of the light receiving element 222 at an angle β less than 15 degrees with respect to vertical light, because the upper curvature of the micro lens 226 is limited as described above. Accordingly, the light incident on the top surface of the IR filter layer 224 is also incident at an angle less than 15 degrees with respect to vertical light such that infrared light included in most light is reflected, which makes it possible to maximize an IR shielding effect.

Therefore, an amount of infrared light incident on the image sensor 220 is minimized, so that a color shift phenomenon of the image sensor 220 can be effectively prevented.

Now, a method of manufacturing the image sensor according to the second embodiment of the invention will be described.

As shown in FIG. 9, the method includes the steps of: forming a plurality of light receiving elements 222 on a wafer 221; forming a metal layer 223 on the light receiving elements 222; forming an IR filter layer 224 on the metal layer 223, the IR filter layer 224 having a plane surface parallel to an array direction of the light receiving elements 222; forming a color filter 225 on the IR filter layer 224 such that the color filter 225 overlaps the light receiving elements 222; and forming a plurality of micro lenses 126 on the color filter 225.

The IR filter layer 224 is formed by the vacuum thin-film deposition technique such that the thickness thereof is uniform. Further, the top surface of the IR filter layer 225 is formed in parallel to the array direction of the light receiving elements 222 such that the refractive index thereof is uniform. Then, an IR shielding effect is maximized, and irregular reflection is prevented.

Further, the micro lenses 226 are formed in a hemispheric shape. Preferably, the upper curvature of each micro lens 226 is defined in such a manner that light incident on the IR filter layer 224 is incident at less than 15 degrees with respect to vertical light.

Although not shown, an Anti-Reflection (AR) coating layer or a polarizing filter layer may be formed instead of the IR filter layer formed in the image sensor according to the first and second embodiments. Then, light entering the image sensor can be adjusted. Accordingly, it is possible to manufacture products which can satisfy various demands of users.

In the first and second embodiment of the invention, image sensors before micro lenses are formed are primarily manufactured so as to secure quantities in stock. Further, if necessary, wafers of the image sensors are cleaned. Then, each maker manufactures micro lenses so as to finalize the image sensors. Therefore, it is possible to reliably prevent defects caused by foreign matters.

Further, the IR filter layer may serve as a kind of protective layer so as to protect the pixel array region of the image sensor. As a glass substrate serving as a base of an existing IR shielding member is removed from a light path, it is possible to enhance transmittance and a noise characteristic.

Camera Module

Referring to FIG. 10, a camera module to which the image sensor according to the first and second embodiments is applied will be described.

FIG. 10 is an exploded perspective view of a COB camera module to which the image sensor according to the invention is applied.

As shown in FIG. 10, the camera module according to the invention includes an image sensor 120 or 220 having an IR filter layer formed under a plurality of micro lenses; a substrate 110 having the image sensor 120 or 220 mounted thereon; a housing 140 installed on the substrate 110, and a lens barrel 150 installed on the housing 140, the lens barrel 150 having a lens group L mounted therein.

The camera module according to the invention includes the image sensor 120 or 220 having the IR filter layer formed therein, unlike the conventional camera module having a separate IR shielding member provided therein. Therefore, a process of forming an IR shielding layer on a glass substrate serving as a base of the IR shielding member and a bonding process of mounting the IR shielding member on a housing can be omitted. Therefore, the manufacturing process is simplified so that a manufacturing cost can be reduced. Further, it is possible to prevent defects caused by foreign matters generated during the process.

The IR shielding at the IR filter layer of the image sensor 120 or 220 is maximized, so that infrared light incident on the light receiving elements of the image sensor 120 or 220 is minimized. Then, a color shift phenomenon of the image sensor is effectively prevented, which makes it possible to reproduce a high-quality image.

According to the image sensor, the method of manufacturing the same, and the camera module having the same, an amount of infrared light incident on the image sensor is minimized so that a defective image can be prevented and a high-quality image can be displayed.

Further, the number of processes can be reduced, so that a manufacturing time and cost can be reduced.

Furthermore, defects caused by foreign matters are effectively prevented, which makes it possible to enhance product reliability and productivity.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image sensor comprising:
a wafer;
a plurality of light receiving elements provided on the wafer;
a color filter provided above the light receiving elements so as to overlap the light receiving elements;
an infrared (IR) filter layer provided on the color filter, the IR filter layer having a plane surface parallel to an array direction of the light receiving elements; and
a plurality of micro lenses provided on the IR filter layer.

2. The image sensor according to claim 1, wherein the IR filter is formed by a vacuum thin-film deposition technique.

3. The sensor according to claim 1, wherein each of the micro lenses has such an upper curvature that light incident on the IR filter layer through the micro lens is incident at less than 15 degrees with respect to vertical light.

4. An image sensor comprising:
a wafer;
a plurality of light receiving elements provided on the wafer;
an IR filter layer provided above the light receiving elements, the IR filter layer having a plane surface parallel to an array direction of the light receiving elements;
a color filter provided on the IR filter layer so as to overlap the light receiving elements; and
a plurality of micro lenses provided on the color filter.

5. The sensor according to claim 4, wherein each of the micro lenses has such an upper curvature that light incident on the IR filter layer through the micro lens is incident at less than 15 degrees with respect to vertical light.

6. A method of manufacturing an image sensor, the method comprising the steps of:
forming a plurality of light receiving elements on a wafer;
forming a color filter above the light receiving elements such that the color filter overlaps the light receiving elements;
forming an IR filter layer on the color filter, the IR filter layer having a plane surface parallel to an array direction of the light receiving elements; and
forming a plurality of micro lenses on the IR filter layer.

7. The method according to claim 6, wherein each of the micro lenses has such an upper curvature that light incident on the IR filter layer through the micro lens is incident at less than 15 degrees with respect to vertical light.

8. A method of manufacturing an image sensor, the method comprising the steps of:
forming a plurality of light receiving elements on a wafer;
forming an IR filter layer above the light receiving elements, the IR filter layer having a plane surface parallel to an array direction of the light receiving elements;
forming a color filter on the IR filter layer such that the color filter overlaps the light receiving elements; and
forming a plurality of micro lenses on the color filter.

9. The method according to claim 6, wherein each of the micro lenses has such an upper curvature that light incident on the IR filter layer through the micro lens is incident at less than 15 degrees with respect to vertical light.

10. A camera module comprising:
an image sensor including:
a wafer;
a plurality of light receiving elements provided on the wafer;
a color filter provided above the light receiving elements so as to overlap the light receiving elements;
an IR filter layer provided on the color filter, the IR filter layer having a plane surface parallel to an array direction of the light receiving elements; and
a plurality of micro lenses provided on the IR filter layer;
a substrate having the image sensor mounted thereon;
a housing installed on the substrate; and
a lens barrel installed on the housing and having a lens group mounted thereon.

11. A camera module comprising:
an image sensor including:
a wafer;
a plurality of light receiving elements provided on the wafer;
an IR filter layer provided above the light receiving elements, the IR filter layer having a plane surface parallel to an array direction of the light receiving elements;
a color filter provided on the IR filter layer so as to overlap the light receiving elements; and
a plurality of micro lenses provided on the color filter;
a substrate having the image sensor mounted thereon;
a housing installed on the substrate; and
a lens barrel installed on the housing and having a lens group mounted thereon.
